(19) United States
(12) Patent Application Publication
(10) Pub. No.: US 2008/0251885 A1
(43) Pub. Date: Oct. 16, 2008

(54) Fuse structure, semiconductor device, and method of forming the semiconductor device

(75) Inventor: Hirotaka Kobayashi, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Elpida Memory, Inc., Tokyo (JP)

(21) Appl. No.: 12/078,842

(22) Filed: Apr. 7, 2008

(30) Foreign Application Priority Data
Apr. 12, 2007 (JP) P2007-104689

(51) Int. Cl. H01L 23/00; H01L 21/00

(52) U.S. Cl. 257/529; 438/601; 257/E23.149; 257/E21.592

(57) ABSTRACT

There are provided a fuse structure and a semiconductor device having the fuse structure. The fuse structure includes an insulating layer having a hole, a resistance-variable material layer disposed on inner wall of the hole, a reference power layer that covers the resistance-variable material layer, and a plurality of leads in the insulating layer. Each lead has a first portion which reaches the inner wall of the hole and contacts the resistance-variable material layer. Each lead is configured to allow an electrical connection to outside.

### BACKGROUND OF THE INVENTION

1. Field of the Invention

The present invention generally relates to a fuse structure, a semiconductor device, and a method of forming the semiconductor device. More specifically, the present invention relates to a fuse structure that allows high density integration of fuses, each of which is configured to change its conductive states in accordance with an external electrical signal, as well as a semiconductor device and a method of forming the semiconductor device.

Priority is claimed on Japanese Patent Application No. 2007-104689, filed Apr. 12, 2007, the content of which is incorporated herein by reference.

2. Description of the Related Art

All patents, patent applications, patent publications, scientific articles, and the like, which will hereinafter be cited or identified in the present application, will hereby be incorporated by reference in their entirety in order to describe more fully the state of the art to which the present invention pertains.

Fuses can be used for relief of a defect of a semiconductor device, the effect having been generated in manufacturing process of the semiconductor device. Fuses can also be used to change the layout of interconnection layers while changing circuit interconnection information in response to a variety of products. There has been high requirement for rewriting relief information and circuit interconnection information in a semiconductor chip as packaged, by way of input of an external electric signal into the packaged semiconductor chip. Various conventional countermeasures to satisfy this requirement have been proposed.

Japanese Unexamined Patent Application, First Publication, No. 6-310604 discloses a conventional semiconductor device including antifuses. The antifuse is a device that is designed to start with a high resistance and to permanently create an electrically conductive path by breaking an insulating layer of the antifuse, typically when the voltage exceeding a certain level is applied across the antifuse. The antifuse once created the electrically conductive path can no longer be placed again in the original highly resistive state.

Japanese Unexamined Patent Application, First Publication, No. 2005-317713 discloses a conventional semiconductor device including a phase change film that performs as a resettable fuse. The resettable fuse can be designed to be easily changed in conductivity and resettable between the highly conductive state and the highly insulative state. The phase change film is made of a phase change material. The phase change film is used as a wiring or an interconnection. A heater is provided near the phase change film. The heater changes the phase of the phase change film so as to transition a highly resistive amorphous state into a lowly resistive crystal state thereby decreasing the resistance of the phase change film or to transition the lowly resistive crystal state into the highly resistive amorphous state thereby increasing the resistance of the phase change film. The heater used to change the resistance of the phase change film results in a large size of each fuse. This publication also discloses eliminating a heater and in place using electrodes that apply a current across the phase change film, thereby generating heat at the phase change film and changing the crystal state of the phase change film. This alternating proposal simplifies the structure of the fuse that changes the crystal state of the phase change film. Such simplification of the fuse structure reduces the size of each element but insufficiently and further reduction in size of each element is required.

Japanese Unexamined Patent Application, First Publication, No. 2006-222215 discloses a conventional phase change memory that settles the problems with the difficulty in size reduction of each element. The phase change memory has a top electrode, a phase change film, and a bottom electrode plug which connects the phase change film to a bottom electrode plate as a common plate. The phase change film is made of chalcogenide. Current application to the bottom electrode plug causes heat generation which transitions between a highly resistive amorphous state and a lowly resistive crystal state, thereby realizing a bit-information-rewritable phase change memory. The plain area of the phase change element corresponds to the plain area of the bottom electrode plug. This allows high density integration of a large number of the phase change memory elements as unit elements and allows a very limited area to have many bit information.

Japanese Unexamined Patent Application, First Publication, No. 6-232271 discloses a material for interconnection which can vary electrical resistance by light irradiation, voltage application and heat application, wherein the material includes at least two elements that are selected from the group consisting of Ge, Te, Sb and In.

In accordance with the conventional phase change memory disclosed in Japanese Unexamined Patent Application, First Publication, No. 2006-222215, at least two interconnection layers partially performing as top and bottom electrodes are disposed over and under the phase change film of chalcogenide. The presence of the at least two interconnection layers as the top and bottom electrodes makes it difficult to reduce the plain area for disposing the fuse. The conventional phase change memory has the issue to further reduce the plain area for layout of the fuse and to increase the density of integration of the fuses in a limited area.

In view of the above, it will be apparent to those skilled in the art from this disclosure that there exists a need for an improved fuse structure, a semiconductor device, and a method of forming the semiconductor device. This invention addresses this need in the art as well as other needs, which will become apparent to those skilled in the art from this disclosure.

### SUMMARY OF THE INVENTION

Accordingly, it is a primary object of the present invention to provide a fuse structure.

It is another object of the present invention to provide a fuse structure that allows reduction in plain area for layout of a fuse.

It is a further object of the present invention to provide a fuse structure that allows high density integration of fuses in a limited area.

It is a still further object of the present invention to provide a semiconductor device that has a high density integration of fuses.

It is yet a further object of the present invention to provide a method of forming a semiconductor device that has a high density integration of fuses.

In accordance with a first aspect of the present invention, a fuse structure may include, but is not limited to, an insulating layer having a hole, a resistance-variable material layer disposed on inner wall of the hole, a reference power layer that covers the resistance-variable material layer, and a plurality of leads in the insulating layer. Each lead has a first portion which reaches the inner wall of the hole and contacts the resistance-variable material layer. Each lead is configured to allow an electrical connection to outside.

In some cases, the resistance-variable material layer may be made of a phase change material.

In some cases, the resistance-variable material layer may be made of perovskite-type metal oxide.

In some cases, the insulating layer may include, but is not limited to, a first insulating layer and a second insulating layer over the first insulating layer. The hole may include a lower portion in the first insulating layer and an upper portion in the second insulating layer. The resistance-variable material layer may cover at least part of inner wall of the lower portion of the hole and at least part of inner wall of the upper portion of the hole. The plurality of leads may extend over the first insulating layer and under the second insulating layer.

In some cases, the insulating layer may include, but is not limited to, a first insulating layer, a second insulating layer over the first insulating layer, and a third insulating layer over the second insulating layer. The hole may include a lower portion in the first insulating layer, an intermediate portion in the second insulating layer, and an upper portion in the third insulating layer. The resistance-variable material layer may cover at least part of inner wall of the lower portion of the hole, at least part of inner wall of the intermediate portion of the hole, and at least part of inner wall of the upper portion of the hole. The plurality of leads may include a first group of leads that extends over the first insulating layer and under the second insulating layer, and a second group of leads that extends over the second insulating layer and under the third insulating layer.

In accordance with a second aspect of the present invention, a semiconductor device includes a fuse structure. The fuse structure may include an insulating layer having a hole, a resistance-variable material layer disposed on inner wall of the hole, a reference power layer that covers the resistance-variable material layer, and a plurality of leads in the insulating layer. Each lead has a first portion which reaches the inner wall of the hole and contacts the resistance-variable material layer. Each lead is configured to allow an electrical connection to outside.

In some cases, the resistance-variable material layer may be made of a phase change material.

In some cases, the resistance-variable material layer may be made of perovskite-type metal oxide.

In some cases, the insulating layer may include a first insulating layer and a second insulating layer over the first insulating layer. The hole may include a lower portion in the first insulating layer and an upper portion in the second insulating layer. The resistance-variable material layer may cover at least part of inner wall of the lower portion of the hole and at least part of inner wall of the upper portion of the hole. The plurality of leads may extend over the first insulating layer and under the second insulating layer.

In some cases, the insulating layer may include a first insulating layer, a second insulating layer over the first insulating layer, and a third insulating layer over the second insulating layer. The hole may include a lower portion in the first insulating layer, an intermediate portion in the second insulating layer, and an upper portion in the third insulating layer. The resistance-variable material layer may cover at least part of inner wall of the lower portion of the hole, at least part of inner wall of the intermediate portion of the hole, and at least part of inner wall of the upper portion of the hole. The plurality of leads may include a first group of leads that extends over the first insulating layer and under the second insulating layer, and a second group of leads that extends over the second insulating layer and under the third insulating layer.

In accordance with a third aspect of the present invention, a semiconductor device may include, but is not limited to, an insulating layer, a fuse structure, and a hole pattern. The insulating layer may include a first insulating layer and a second insulating layer over the first insulating layer. The insulating layer may have a fuse region having a first hole and a peripheral circuit region having a second hole. The first hole may include an lower portion in the first insulating layer and an upper portion in the second insulating layer. The fuse structure is present in the first hole in the fuse region. The fuse structure may include, but is not limited to, a resistance-variable material layer, a reference power layer, and a plurality of leads. The resistance-variable material layer may be disposed on inner wall of the first hole. The reference power layer may include a conductive portion in the first hole and a conductive interconnection layer extending over the second insulating layer and the conductive portion. The conductive portion covers the resistance-variable material layer. The plurality of leads may extend over the first insulating layer and under the second insulating layer in the fuse region. Each lead has a first portion which reaches the inner wall of the hole and contacts the resistance-variable material layer. Each lead is configured to allow an electrical connection to outside. The hole pattern for peripheral circuit is present in the second hole in the peripheral circuit region. The hole pattern may include, but is not limited to, a first interconnection layer, a second interconnection layer, and a via contact. The first interconnection layer may extend over the first insulating layer and under the second insulating layer in the peripheral circuit region. The second interconnection layer may extend over the second insulating layer in the peripheral circuit region. The via contact may penetrate through the second insulating layer in the peripheral circuit region. The via contact provides an electrical connection between the first and second interconnection layers. The first interconnection layer and the plurality of leads may be made of the same material. The via contact and the conductive portion of the reference power layer may be made of the same material. The second interconnection layer and the conductive interconnection layer of the reference power layer may be made of the same material.

In accordance with a fourth aspect of the present invention, a method of forming a semiconductor device may include, but is not limited to the following processes. A first insulating layer is formed over a semiconductor substrate. First and second interconnection layers are formed over the first insulating layer. A second insulating layer is formed which covers the first and second interconnection layers. A first hole is formed, which penetrates the second insulating layer so that the edge portion of the first interconnection layer is shown on the inner wall of the first hole. A resistance-variable material layer is formed on the inner wall of the first hole so that the resistance-variable material layer contacts the edge portion of the first interconnection layer. A second hole is formed, which penetrates the second insulating layer, so that a part of the second interconnection is shown through the second hole. The first and second holes are filled with a conductive material concurrently.

In some cases, the first interconnection layer may include, but is not limited to, a plurality of interconnection layers. The first hole may be formed so that the edge portions of the plurality of interconnection layers are shown on the inner wall of the first hole.

In some cases, forming the first hole may include, but is not limited to, forming a first hole that penetrates the second insulating layer and reaches an intermediate level of the first insulating layer.

In some cases, the resistance-variable material layer may be made of a phase change material.

In some cases, the resistance-variable material layer may be made of perovskite-type metal oxide.

In accordance with the above-described first to fourth aspects of the present invention, the fuse structure may include, but is not limited to, an insulating layer having a hole, a resistance-variable material layer disposed on inner wall of the hole, a reference power layer that covers the resistance-variable material layer, and a plurality of leads in the insulating layer. Each lead has a first portion which reaches the inner wall of the hole and contacts the resistance-variable material layer. Each lead is configured to allow an electrical connection to outside.

The resistance-variable material layer extends along the walls of the hole of the insulating layer. The hole has a depth direction that is parallel to the thickness direction of the insulating layer. The walls of the hole may in general extend in the thickness direction of the insulating layer. Thus, the resistance-variable material layer may in general extend in the thickness direction of the insulating layer. This layout of the resistance-variable material layer extending in the thickness direction of the insulating layer can further reduce the plain area necessary for layout for the fuses as compared to the layout for the resistance-variable material layer extending in parallel to the surface of the insulating layer. The layout of the resistance-variable material layer extending in the thickness direction of the insulating layer can increase the density of integration of the fuses as compared to the layout for the resistance-variable material layer extending in parallel to the surface of the insulating layer. The layout of the resistance-variable material layer extending in the thickness direction of the insulating layer does not need any via contact, thereby increasing the flexibility of design and layout of the fuses as compared to the fuse structure that needs the via contact.

The layout for the resistance-variable material layer extending in parallel to the surface of the insulating layer is the traditionally and historically employed layout that lies in the common technical sense to a person skilled in the art to which the invention pertains. The layout of the resistance-variable material layer extending in the thickness direction of the insulating layer is away from the technical common sense, for example, the traditionally and historically employed layout for the resistance-variable material layer but extending in parallel to the surface of the insulating layer.

The fuse structure that needs via contact is the traditionally and historically employed fuse structure which lies in the common technical sense to a person skilled in the art to which the invention pertains. The fuse structure free of any via contact is away from the technical common sense, for example, the traditionally and historically employed fuse structure that needs via contact. The fuse structure free of any via contact provides increased flexibility in laying out the fuses.

These and other objects, features, aspects, and advantages of the present invention will become apparent to those skilled in the art from the following detailed descriptions taken in conjunction with the accompanying drawings, illustrating the embodiments of the present invention.

### BRIEF DESCRIPTION OF THE DRAWINGS

Referring now to the attached drawings which form a part of this original disclosure:

FIG. 1 is a plain view illustrating a fuse structure that is provided in a semiconductor device in accordance with a first preferred embodiment of the present invention;

FIG. 2 is a fragmentary cross sectional elevation view, taken along an A-A′ line of FIG. 1, which illustrates the fuse structure that is provided in the semiconductor device;

FIG. 3 is a fragmentary cross sectional elevation view illustrating one step involved in a process for forming the fuse structure shown in FIGS. 1 and 2;

FIG. 4 is a fragmentary cross sectional elevation view illustrating a step subsequent to the step of FIG. 3, involved in a process for forming the fuse structure shown in FIGS. 1 and 2;

FIG. 5 is a fragmentary cross sectional elevation view illustrating a step subsequent to the step of FIG. 4, involved in a process for forming the fuse structure shown in FIGS. 1 and 2;

FIG. 6 is a fragmentary cross sectional elevation view illustrating a step subsequent to the step of FIG. 5, involved in a process for forming the fuse structure shown in FIGS. 1 and 2;

FIG. 7 is a plain view illustrating a fuse region and a peripheral circuit region of a semiconductor device in accordance with a second preferred embodiment of the present invention;

FIG. 8 is a fragmentary cross sectional elevation view, taken along a B-B′ line of FIG. 7, which illustrates the other fuse structure that is provided in the semiconductor device;

FIG. 9 is a plain view illustrating a fuse structure that is provided in a semiconductor device in accordance with a third preferred embodiment of the present invention; and

FIG. 10 is a fragmentary cross sectional elevation view, taken along a C-C′ line of FIG. 9, which illustrating the fuse structure that is provided in the semiconductor device.

### DETAILED DESCRIPTION OF THE INVENTION

Selected embodiments of the present invention will now be described with reference to the drawings. It will be apparent to those skilled in the art from this disclosure that the following descriptions of the embodiments of the present invention are provided for illustration only and not for the purpose of limiting the invention as defined by the appended claims and their equivalents.

### First Embodiment

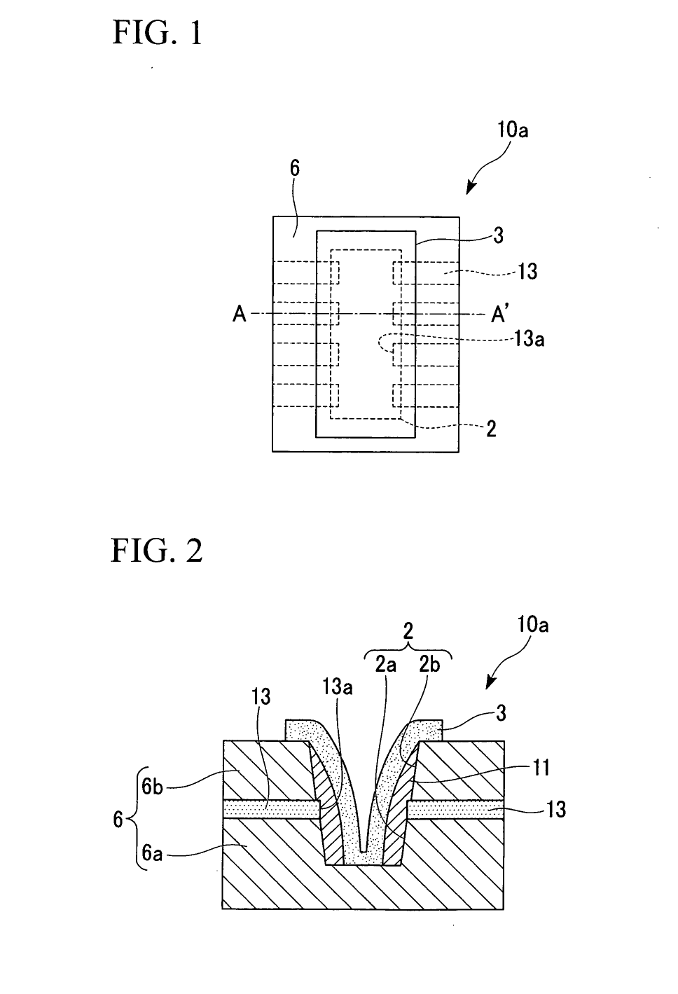

A first embodiment of the present invention will be described. FIG. 1 is a plain view illustrating a fuse structure that is provided in a semiconductor device in accordance with a first preferred embodiment of the present invention. FIG. 2 is a fragmentary cross sectional elevation view, taken along an A-A′ line of FIG. 1, which illustrates the fuse structure that is provided in the semiconductor device.

A fuse structure 10a may include an insulating layer 6. The insulating layer 6 may further include first and second insulating layers 6a and 6b. The second insulating layer 6b extends over the first insulating layer 6a. In some cases, the first and second insulating layers 6a and 6b may be made of silicon oxide.

The insulating layer 6 has a hole 2 which has one opening end and other closing end. The hole 2 may be modified to a slit or a groove. The hole 2 has a lower portion 2a and an upper portion 2b. The lower portion 2a of the hole 2 does not penetrate the first insulating layer 6a. The lower portion 2a of the hole 2 has one opening end and another closed end. The upper portion 2b of the hole 2 penetrates the second insulating layer 6b. The hole 2 has inner walls. The lower portion 2a of the hole 2 has lower inner walls. The upper portion 2a of the hole 2 has upper inner walls.

The fuse structure 10a may further include a resistance-variable material layer 11 that extends along the inner walls of the hole 2. In some cases, the resistance-variable material layer 11 may cover all of the inner walls of the lower portion 2a of the hole 2 and also cover part of the inner walls of the upper portion 2b of the hole 2. The resistance-variable material layer 11 may not cover the bottom surface of the hole 2.

In typical case, the resistance-variable material layer 11 may be realized by a phase change material. A typical example of the phase change material for the resistance-variable material layer 11 may include, but is not limited to, chalcogenide. Examples of chalcogenide may include, but are not limited to, two or more of germanium (Ge), antimony (Sb), tellurium (Te), and selenium (Se). A typical example of the chalcogenide may include, but is not limited to, Ge₂Sb₂Te₅.

The fuse structure 10a may further include a reference power layer 3 which covers the bottom surface of the hole 2, the resistance-variable material layer 11 and a peripheral portion of the top surface of the insulator 6, wherein the peripheral portion surrounds the opening of the hole 2. A typical example of the reference power layer 3 may include, but is not limited to, tungsten. The reference power layer 3 contacts the resistance-variable material layer 11. The reference power layer 3 is adapted to be applied with a reference power voltage so as to allow the reference power layer 3 to perform as a common wiring of the fuse.

The fuse structure 10a may further include a plurality of leads 13. In typical case, the plurality of leads 13 extends over the first insulating layer 6a and under the second insulating layer 6b. Each lead 13 has a first portion 13a and a second portion, wherein the first portion 13a reaches the wall of the hole 2 and which contacts with the resistance-variable material layer 11, and the second portion provides an electrical contact with an external device. In typical cases, the first portion 13a may be a first end of the lead 13 as shown in FIG. 2. The first portion 13a or the first end of each lead 13 can perform as a heater that heats the resistance-variable material layer 11, thereby changing the resistance of the resistance-variable material layer 11. The resistance-variable material layer 11 performs as the same number of fuses as the leads 13 which contact with the resistance-variable material layer 11.

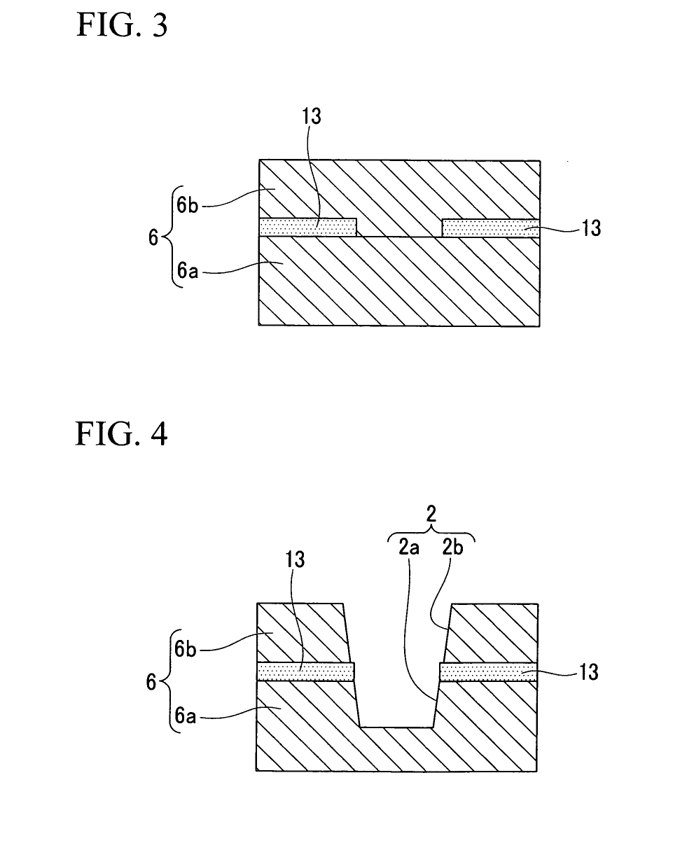

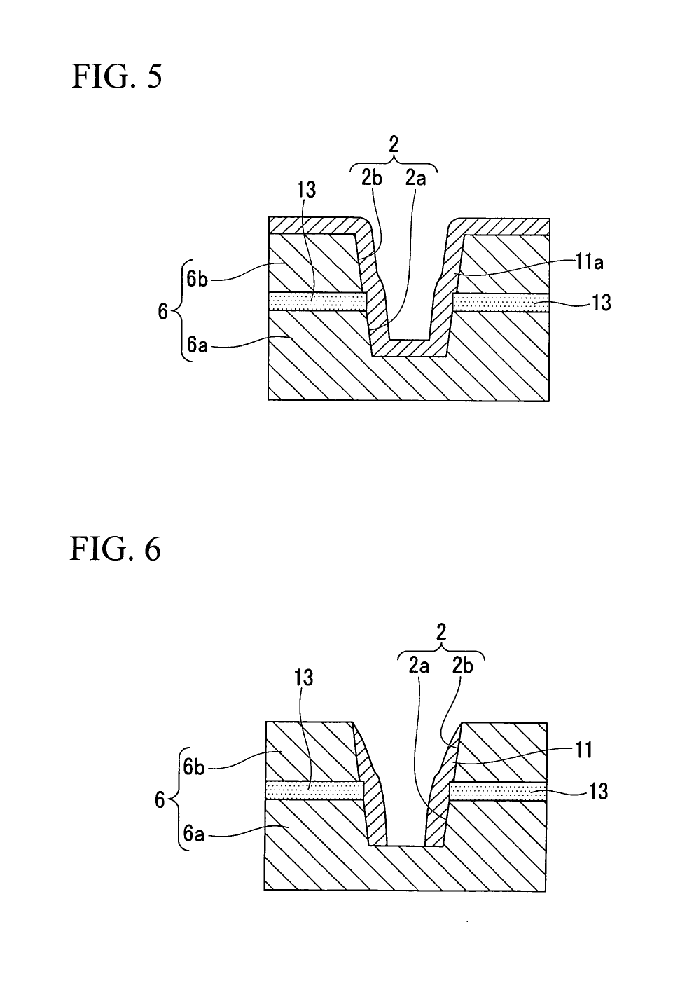

A method of forming the fuse structure of the semiconductor device of FIGS. 1 and 2 will be described with reference to FIGS. 3 through 6. FIG. 3 is a fragmentary cross sectional elevation view illustrating one step involved in a process for forming the fuse structure shown in FIGS. 1 and 2. FIG. 4 is a fragmentary cross sectional elevation view illustrating a step subsequent to the step of FIG. 3, involved in a process for forming the fuse structure shown in FIGS. 1 and 2. FIG. 5 is a fragmentary cross sectional elevation view illustrating a step subsequent to the step of FIG. 4, involved in a process for forming the fuse structure shown in FIGS. 1 and 2. FIG. 6 is a fragmentary cross sectional elevation view illustrating a step subsequent to the step of FIG. 5, involved in a process for forming the fuse structure shown in FIGS. 1 and 2.

As shown in FIG. 3, a first silicon oxide film is formed over a metal oxide semiconductor structure or an interconnection layer. The first silicon oxide film can be formed by a chemical vapor deposition process. The first silicon oxide film may be then planarized by a chemical mechanical polishing process, thereby forming a first insulating layer 6a.

A tungsten film is formed over the planarized surface of the first insulating layer 6a. The tungsten film is patterned by a photo-lithography process and a dry etching process, thereby forming a plurality of leads 13 over the planarized surface of the first insulating layer 6a.

A second silicon oxide film is formed over the plurality of leads 13 and the planarized surface of the first insulating layer 6a. The second silicon oxide film can be formed by a chemical vapor deposition process. The second silicon oxide film may be then planarized by a chemical mechanical polishing process, thereby forming a second insulating layer 6b which extends over the plurality of leads 13 and the planarized surface of the first insulating layer 6a. The first and second insulating layers 6a and 6b in combination form an insulating layer 6.

As shown in FIG. 4, the insulating layer 6 is selectively etched by a photo-lithography process and a dry etching process, thereby forming a hole 2 which has a lower portion 2a and an upper portion 2b. The lower portion 2a of the hole 2 does not penetrate the first insulating layer 6a. The lower portion 2a of the hole 2 has one opening end and another closed end. The upper portion 2b of the hole 2 penetrates the second insulating layer 6b. The hole 2 has inner walls. The lower portion 2a of the hole 2 has lower inner walls. The upper portion 2a of the hole 2 has upper inner walls. The first portion 13a or the first end of each lead 13 reaches the wall of the hole 2. The first portion 13a or the first end of each lead 13 is shown on the wall of the hole 2.

As shown in FIG. 5, a phase change material film 11a is formed on the bottom surface and the walls of the hole 2 and on the planarized surface of the second insulating layer 6b. The phase change material film 11a contacts with the first portion 13a or the first end of each lead 13. The phase change material film 11a is etched back, thereby removing the phase change material film 1 a over the bottom surface of the hole 2 and over the planarized surface of the second insulating layer 6b, while leaving the phase change material film 11 a on all of the inner walls of the lower portion 2a of the hole 2 and also on part of the inner walls of the upper portion 2b of the hole 2. As a result, a resistance-variable material layer 11 is formed, which covers all of the inner walls of the lower portion 2a of the hole 2 and also cover part of the inner walls of the upper portion 2b of the hole 2. The resistance-variable material layer 11 may not cover the bottom surface of the hole 2. The resistance-variable material layer 11 contacts the first portion 13a or the first end of each lead 13.

As shown in FIG. 2, a tungsten film is formed, which covers the bottom surface of the hole 2, the resistance-variable material layer 11 and the planarized surface of the second insulating layer 6b. The tungsten film is patterned by a photo-lithography process and a dry etching process, thereby forming a reference power layer 3 which covers the bottom surface of the hole 2, the resistance-variable material layer 11 and a peripheral portion of the planarized surface of the insulator 6, wherein the peripheral portion surrounds the opening of the hole 2. The reference power layer 3 contacts with the resistance-variable material layer 11. As a result, the fuse structure 10a is completed.

Operations of the fuse structure 10a will be described with reference again to FIGS. 1 and 2. A current is applied across the resistance-variable material layer 11 between the reference power layer 3 and the plurality of leads 13, so as to change the resistance of the resistance-variable material layer 11. A pulse of current can be adjusted so as to control heat generation of the first portion 13a or the first end of each lead 13 which performs as a heater. The current application heats contact portions of the resistance-variable material layer 11, wherein the contact portions contact with the first portions 13a or the first ends of the plurality of leads 13. Separate adjustment of the application of the current to each lead 13 can separately control the temperature of each contact portion of the resistance-variable material layer 11 in contact with the first portion 13a or the first end of each lead 13. Separate control of the temperature of each contact portion of the resistance-variable material layer 11 can separately control the crystal state of each contact portion of the resistance-variable material layer 11 in contact with the first portion 13a or the first end of each lead 13. Separate control of the crystal state of each contact portion of the resistance-variable material layer 11 can separately control the contact resistance between each contact portion of the resistance-variable material layer 11 and each lead 13.

In some cases, the pulse current applied through each lead 13 to the resistance-variable material layer 11 can be adjusted in pulse width and pulse height to control the crystal state of the contact portion of the resistance-variable material layer 11, thereby controlling the resistance of the contact portion of the resistance-variable material layer 11.

When a pulse of current with a lower pulse height and a wider pulse width is applied through the lead 13 to the resistance-variable material layer 11, crystallization is caused at the phase change material of the contact portion of the resistance-variable material layer 11 in contact with the lead 13, thereby decreasing the resistance of the contact portion of the resistance-variable material layer 11.

When a pulse of current with a higher pulse height and a narrower pulse width is applied through the lead 13 to the resistance-variable material layer 11, amorphization is caused at the phase change material of the contact portion of the resistance-variable material layer 11 in contact with the lead 13, thereby increasing the resistance of the contact portion of the resistance-variable material layer 11.

Namely, adjustments in pulse width and height of the pulse current can control the transition of the phase or the crystal state of the contact portion of the resistance-variable material layer 11, thereby changing the resistance of the contact portion of the resistance-variable material layer 11.

The fuse structure 10a is configured to change the resistance between the reference power layer 3 and each of the plurality of leads 13. Application of external electric signal through the leads 13 to the resistance-variable material layer 11 can rewrite relief information and circuit interconnection information in a semiconductor device. The fuse structure 10a can rewrite relief information and circuit interconnection information in a semiconductor chip as packaged, by way of input of an external electric signal into the packaged semiconductor chip.

The semiconductor device includes the fuse structure 10a that includes the insulating layer 6 having the hole 2 having the walls, the resistance-variable material layer 11 extending along the walls of the hole 2, the reference power layer 3 covering the resistance-variable material layer 11, the plurality of leads 13. Each lead 13 has the first portion 13a that reaches the wall of the hole and contacts with the resistance-variable material layer 11, and the second portion that is electrically connected to an external device. The resistance-variable material layer 11 performs as fuses. Namely, the resistance-variable material layer 11 has the contact portions that contact with the first portions 13a of the plurality of leads 13. Each contact portion of the resistance-variable material layer 11 performs a fuse. The resistance-variable material layer 11 has alignments of fuses.

The resistance-variable material layer 11 extends along the walls of the hole 2 of the insulating layer 6. The hole 2 has a depth direction that is parallel to the thickness direction of the insulating layer 6. The walls of the hole 2 extends in the thickness direction of the insulating layer 6. Thus, the resistance-variable material layer 11 extends in the thickness direction of the insulating layer 6. This layout of the resistance-variable material layer 11 extending in the thickness direction of the insulating layer 6 can further reduce the plain area necessary for layout for the fuses as compared to the layout for the resistance-variable material layer extending in parallel to the surface of the insulating layer 6. The layout of the resistance-variable material layer 11 extending in the thickness direction of the insulating layer 6 can increase the density of integration of the fuses as compared to the layout for the resistance-variable material layer extending in parallel to the surface of the insulating layer 6. The layout of the resistance-variable material layer 11 extending in the thickness direction of the insulating layer 6 does not need any via contact, thereby increasing the flexibility of design and layout of the fuses as compared to the fuse structure that needs the via contact.

The layout for the resistance-variable material layer extending in parallel to the surface of the insulating layer 6 is the traditionally and historically employed layout that lies in the common technical sense to a person skilled in the art to which the invention pertains. The layout of the resistance-variable material layer 11 extending in the thickness direction of the insulating layer 6 is away from the technical common sense, for example, the traditionally and historically employed layout for the resistance-variable material layer but extending in parallel to the surface of the insulating layer 6.

The fuse structure that needs via contact is the traditionally and historically employed fuse structure which lies in the common technical sense to a person skilled in the art to which the invention pertains. The fuse structure free of any via contact is away from the technical common sense, for example, the traditionally and historically employed fuse structure that needs via contact. The fuse structure free of any via contact provides increased flexibility in laying out the fuses.

The materials variable for the resistance-variable material layer 11 may include, but are not limited to, the phase change materials, and other materials that vary in its resistivity upon heat application thereto by current application. Examples of the materials variable for the resistance-variable material layer 11 may include, but are not limited to, materials that vary in its resistivity upon application of a voltage or a current thereto, and the materials such as perovskite-type metal oxide that maintain the changed resistivity even after the voltage or current application was discontinued.

The materials available for the plurality of leads 13 may be conductive materials such as metals, typical examples of which may include, but are not limited to, the above-described metal, aluminum and copper.

In the above-described embodiment, the resistance-variable material layer 11 covers all of the inner walls of the lower portion 2a of the hole 2 and part of the inner walls of the upper portion 2b thereof. It is possible as a modification that the resistance-variable material layer 11 further covers the bottom of the hole 2 in addition to covering all of the inner walls of the lower portion 2a of the hole 2 and part of the inner walls of the upper portion 2b thereof. It is also possible as another modification that the resistance-variable material layer 11 covers part of the inner walls of the lower portion 2a of the hole 2 and part of the inner walls of the upper portion 2b thereof as long as the resistance-variable material layer 11 contacts with each lead 13. It is also possible as another modification that the resistance-variable material layer 11 extends along the wall of the hole 2, so that the resistance-variable material layer 11 contacts with each lead 13.

### Second Embodiment

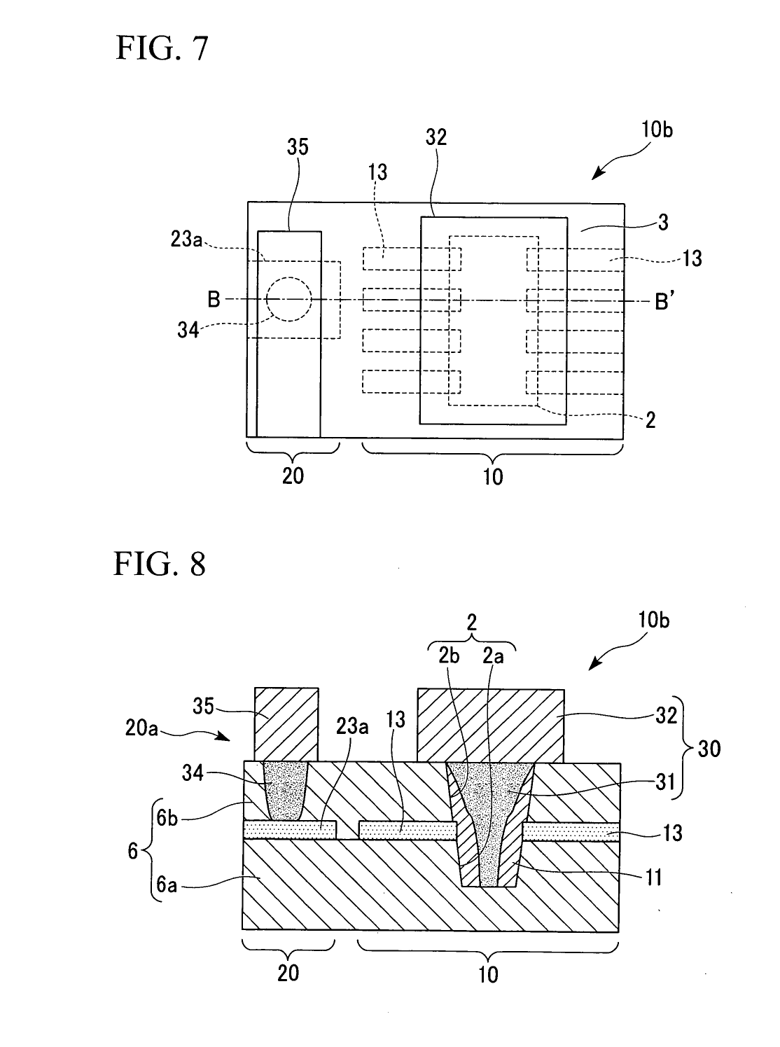

A second embodiment of the present invention will be described. FIG. 7 is a plain view illustrating a fuse region and a peripheral circuit region of a semiconductor device in accordance with a second preferred embodiment of the present invention. FIG. 8 is a fragmentary cross sectional elevation view, taken along a B-B′ line of FIG. 7, which illustrates the other fuse structure that is provided in the semiconductor device.

A semiconductor device includes a fuse region 10 and a peripheral circuit region 20. The fuse region 10 includes a fuse structure 10b. The peripheral circuit region 20 includes a hole pattern 20a for peripheral circuit. The semiconductor device is provided in an insulating layer 6. Namely, the fuse structure 10b and the hole pattern 20a are formed in the insulating layer 6.

The insulating layer 6 may further include first and second insulating layers 6a and 6b. The second insulating layer 6b extends over the first insulating layer 6a. In some cases, the first and second insulating layers 6a and 6b may be made of silicon oxide.

In the fuse region 10, the insulating layer 6 has a hole 2 which has one opening end and other closing end. The hole 2 may be modified to a slit or a groove. The hole 2 has a lower portion 2a and an upper portion 2b. The lower portion 2a of the hole 2 does not penetrate the first insulating layer 6a. The lower portion 2a of the hole 2 has one opening end and another closed end. The upper portion 2b of the hole 2 penetrates the second insulating layer 6b. The hole 2 has inner walls. The lower portion 2a of the hole 2 has lower inner walls. The upper portion 2a of the hole 2 has upper inner walls.

In the fuse region 10, the fuse structure 10b may further include a resistance-variable material layer 11 that extends along the inner walls of the hole 2. In some cases, the resistance-variable material layer 11 may cover all of the inner walls of the lower portion 2a of the hole 2 and also cover part of the inner walls of the upper portion 2b of the hole 2. The resistance-variable material layer 11 may not cover the bottom surface of the hole 2. The materials for the resistance-variable material layer 11 may be the same as described in the first embodiment.

In the fuse region 10, the fuse structure 10b may further include a reference power layer 30 that is different from the reference power layer 3 described in the first embodiment. The reference power layer 30 may fill up the hole 2 in which the resistance-variable material layer 11 is present and also may extend over the hole 2 and the second insulating layer 6b. In some cases, the reference power layer 30 has a conductive portion 31 and a conductive interconnection layer 32. The conductive portion 31 is present in the hole 2 to full up the hole 2, while the conductive portion 31 contacts with the resistance-variable material layer 11. The conductive portion 31 covers the resistance-variable material layer 11 and the bottom surface of the hole 2. The conductive interconnection layer 32 is present over the conductive portion 31 in the hole 2 and a peripheral portion of the top surface of the insulator 6, wherein the peripheral portion surrounds the opening of the hole 2. The reference power layer 30 may be made of a conductor. A typical example of the conductive portion 31 may include, but is not limited to, tungsten. The reference power layer 30 is adapted to be applied with a reference power voltage so as to allow the reference power layer 30 to perform as a common wiring of the fuse.

In the fuse region 10, the fuse structure 10b may further include a plurality of leads 13. In typical case, the plurality of leads 13 extends over the first insulating layer 6a and under the second insulating layer 6b. Each lead 13 has a first portion and a second portion, wherein the first portion 13a reaches the wall of the hole 2 and which contacts with the resistance-variable material layer 11, and the second portion provides an electrical contact with an external device. In typical cases, the first portion may be a first end of the lead 13 as shown in FIG. 8. The first portion 13a or the first end of each lead 13 can perform as a heater that heats the resistance-variable material layer 11, thereby changing the resistance of the resistance-variable material layer 11. The resistance-variable material layer 11 performs as the same number of fuses as the leads 13 which contact with the resistance-variable material layer 11.

In the peripheral circuit region 20, the hole pattern 20a for peripheral circuit may include, but is not limited to, a first interconnection layer 23a, a via contact 34 and a second interconnection layer 35. The first interconnection layer 23a extends over the first insulating layer 6a and under the second insulating layer 6b. The second interconnection layer 35 extends over the top surface of the second insulating layer 6b. The via contact 34 is present in a via hole which penetrate the second insulating layer 6b and reaches the first interconnection layer 23a. The second interconnection layer 35 contacts with the top portion of the via contact 34. The first interconnection layer 23a contacts with the bottom portion of the via contact 34. The via contact 34 provides electrical connection between the first and second interconnection layers 23a and 35.

In some cases, the first interconnection layer 23a may be made of the same material as the leads 13, and the second interconnection layer 35 may be made of the same material as the conductive interconnection layer 32.

A method of forming the semiconductor device of FIGS. 7 and 8 will be described. In typical cases, the fuse structure 10b and the hole pattern 20a for peripheral circuit may be formed in the common set of sequential processes as follows.

A first silicon oxide film is formed over a metal oxide semiconductor structure or an interconnection layer. The first silicon oxide film can be formed by a chemical vapor deposition process. The first silicon oxide film may be then planarized by a chemical mechanical polishing process, thereby forming a first insulating layer 6a.

A tungsten film is formed over the planarized surface of the first insulating layer 6a. The tungsten film is patterned by a photo-lithography process and a dry etching process, thereby forming a plurality of leads 13 and a first interconnection layer 23a. The plurality of leads 13 extends over the planarized surface of the first insulating layer 6a in the fuse region 10. The first interconnection layer 23a extends over the planarized surface of the first insulating layer 6a in the peripheral circuit region 20.

A second silicon oxide film is formed over the plurality of leads 13, the first interconnection layer 23a and the planarized surface of the first insulating layer 6a. The second silicon oxide film can be formed by a chemical vapor deposition process. The second silicon oxide film may be then planarized by a chemical mechanical polishing process, thereby forming a second insulating layer 6b which extends over the plurality of leads 13 and the planarized surface of the first insulating layer 6a. The first and second insulating layers 6a and 6b in combination form an insulating layer 6.

A first resist film is applied on the planarized surface of the second insulating layer 6b. A photo-lithography process is carried out to form a first resist pattern on the planarized surface of the second insulating layer 6b. A dry etching process is carried out using the first resist pattern as a mask to selectively etch the insulating layer 6, thereby forming a hole 2 in the insulating layer 6 in the fuse region 10. The hole 2 has a lower portion 2a and an upper portion 2b. The lower portion 2a of the hole 2 does not penetrate the first insulating layer 6a. The lower portion 2a of the hole 2 has one opening end and another closed end. The upper portion 2b of the hole 2 penetrates the second insulating layer 6b. The hole 2 has inner walls. The lower portion 2a of the hole 2 has lower inner walls. The upper portion 2a of the hole 2 has upper inner walls. The first portion 13a or the first end of each lead 13 reaches the wall of the hole 2. The first portion 13a or the first end of each lead 13 is shown on the wall of the hole 2. The first resist pattern is removed.

A phase change material film 11a as shown in FIG. 5 is formed on the bottom surface and the walls of the hole 2 and on the planarized surface of the second insulating layer 6b, whereby the phase change material film 11a contacts with the first portion 13a or the first end of each lead 13. The phase change material film 11a is etched back, thereby removing the phase change material film 11 a over the bottom surface of the hole 2 and over the planarized surface of the second insulating layer 6b, while leaving the phase change material film 11 a on all of the inner walls of the lower portion 2a of the hole 2 and also on part of the inner walls of the upper portion 2b of the hole 2. As a result, a resistance-variable material layer 11 is formed in the hole 2 in the fuse region 10. The resistance-variable material layer 11 covers all of the inner walls of the lower portion 2a of the hole 2 and also cover part of the inner walls of the upper portion 2b of the hole 2. The resistance-variable material layer 11 may not cover the bottom surface of the hole 2. The resistance-variable material layer 11 contacts the first portion 13a or the first end of each lead 13 in the fuse region.

A second resist film is applied on the planarized surface of the second insulating layer 6b. A photo-lithography process is carried out to form a second resist pattern on the planarized surface of the second insulating layer 6b. A dry etching process is carried out using the second resist pattern as a mask to selectively etch the insulating layer 6, thereby forming a through hole in the peripheral circuit region 20. The through hole reaches the first interconnection layer 23a so that a part of the first interconnection layer 23a is shown through the through hole.

A tungsten film is formed in the hole 2 with the presence of the resistance-variable material layer 11 and in the through hole as well as over the surface of the second insulating layer 6b. The tungsten film fills up the hole 2 with the resistance-variable material layer 11 and the through hole. The tungsten film covers the bottom surface of the hole 2, the resistance-variable material layer 11, bottom and walls of the through hole and the planarized surface of the second insulating layer 6b. The tungsten film contacts with the resistance-variable material layer 11 in the hole 2 in the fuse region 10 as well as contacts with the first interconnection layer 23a in the through hole in the peripheral circuit region 20.

A chemical mechanical polishing process is carried out to planarize the tungsten film, thereby removing the tungsten film over the surface of the second insulating layer 6b, while leaving the tungsten film in the hole 2 with the presence of the resistance-variable material layer 11 and in the through hole. As a result, a conductive portion 31 is formed in the hole 2 with the presence of the resistance-variable material layer 11 in the fuse region 10, while a via contact 34 is formed in the through hole in the peripheral circuit region 20. The conductive portion 31 contacts with the resistance-variable material layer 11 in the hole 2. The via contact 34 contacts the first interconnection layer 23a in the through hole. The conductive portion 31 fills up the hole 2 with the presence of the resistance-variable material layer 11. The via contact 34 fills up the through hole. The conductive portion 31 and the via contact 34 are formed in the common processes.

Another tungsten film is formed over the surface of the second insulating layer 6b as well as over the conductive portion 31 and the via contact 34. The tungsten film contacts with the conductive portion 31 and the via contact 34.

A third resist film is applied on the tungsten film. A photo-lithography process is carried out to form a third resist pattern on the tungsten film. A dry etching process is carried out using the third resist pattern as a mask to selectively etch the tungsten film, thereby forming a conductive interconnection layer 32 in the fuse region 10 and a second interconnection layer 35 in the peripheral circuit region 20. The conductive interconnection layer 32 extends over the second insulating layer 6b in the fuse region 10. The second interconnection layer 35 extends over the second insulating layer 6b in the peripheral circuit region 20. The conductive interconnection layer 32 contacts the conductive portion 31 in the fuse region 10. The combination of the conductive portion 31 and the conductive interconnection layer 32 performs a reference power layer 30 to which a reference power such as a reference voltage or current is applied from the outside. The conductive interconnection layer 32 is electrically connected through the conductive portion 31 and the resistance-variable material layer 11 to the leads 13 in the fuse region 10. The second interconnection layer 35 contacts the via contact 34 in the peripheral circuit region 20. The second interconnection layer 35 is eclectically connected through the via contact 34 to the first interconnection layer 23 in the peripheral circuit region 20. The conductive interconnection layer 32 and the second interconnection layer 35 are formed in the common processes.

As a result, the fuse structure 10b and the hole pattern 20a for peripheral circuit are thus formed in the fuse region 10 and the peripheral circuit region 20, respectively through partially common processes.

Operations of the fuse structure 10b shown in FIGS. 7 and 8 will be described. A current is applied across the resistance-variable material layer 11 between the reference power layer 30 and the plurality of leads 13, so as to change the resistance of the resistance-variable material layer 11. A pulse of current can be adjusted so as to control heat generation of the first portion 13a or the first end of each lead 13 which performs as a heater. The current application heats contact portions of the resistance-variable material layer 11, wherein the contact portions contact with the first portions 13a or the first ends of the plurality of leads 13. Separate adjustment of the application of the current to each lead 13 can separately control the temperature of each contact portion of the resistance-variable material layer 11 in contact with the first portion 13a or the first end of each lead 13. Separate control of the temperature of each contact portion of the resistance-variable material layer 11 can separately control the crystal state of each contact portion of the resistance-variable material layer 11 in contact with the first portion 13a or the first end of each lead 13. Separate control of the crystal state of each contact portion of the resistance-variable material layer 11 can separately control the contact resistance between each contact portion of the resistance-variable material layer 11 and each lead 13.

In some cases, the pulse current applied through each lead 13 to the resistance-variable material layer 11 can be adjusted in pulse width and pulse height to control the crystal state of the contact portion of the resistance-variable material layer 11, thereby controlling the resistance of the contact portion of the resistance-variable material layer 11. Application of a pulse of current with a lower pulse height and a wider pulse width through the lead 13 to the resistance-variable material layer 11 causes crystallization at the phase change material of the contact portion of the resistance-variable material layer 11 in contact with the lead 13. The crystallization decreases the resistance of the contact portion of the resistance-variable material layer 11. Application of a pulse of current with a higher pulse height and a narrower pulse width through the lead 13 to the resistance-variable material layer 11 causes amorphization at the phase change material of the contact portion of the resistance-variable material layer 11 in contact with the lead 13. The amorphization increases the resistance of the contact portion of the resistance-variable material layer 11. Thus, adjustments in pulse width and height of the pulse current can control the transition of the phase or the crystal state of the contact portion of the resistance-variable material layer 11, thereby changing the resistance of the contact portion of the resistance-variable material layer 11.

The semiconductor device shown in FIGS. 7 and 8 has the fuse region 10 and the peripheral circuit region 20. The fuse region 10 includes the fuse structure 10b. The fuse structure 10b is configured to change the resistance between the reference power layer 3 and each of the plurality of leads 13. Application of external electric signal through the leads 13 to the resistance-variable material layer 11 can rewrite relief information and circuit interconnection information in a semiconductor device. Thus, the fuse structure 10b can rewrite relief information and circuit interconnection information in a semiconductor chip as packaged, by way of input of an external electric signal into the packaged semiconductor chip.

The resistance-variable material layer 11 performs as fuses. The resistance-variable material layer 11 extends along the walls of the hole 2 of the insulating layer 6. Thus, the resistance-variable material layer 11 extends in the thickness direction of the insulating layer 6. This layout of the resistance-variable material layer 11 extending in the thickness direction of the insulating layer 6 can further reduce the plain area necessary for layout for the fuses as compared to the layout for the resistance-variable material layer extending in parallel to the surface of the insulating layer 6. The layout of the resistance-variable material layer 11 extending in the thickness direction of the insulating layer 6 can increase the density of integration of the fuses as compared to the layout for the resistance-variable material layer extending in parallel to the surface of the insulating layer 6. The layout of the resistance-variable material layer 11 extending in the thickness direction of the insulating layer 6 does not need any via contact, thereby increasing the flexibility of design and layout of the fuses as compared to the fuse structure that needs the via contact.

In the above-described embodiment, the resistance-variable material layer 11 covers all of the inner walls of the lower portion 2a of the hole 2 and part of the inner walls of the upper portion 2b thereof. It is possible as a modification that the resistance-variable material layer 11 further covers the bottom of the hole 2 in addition to covering all of the inner walls of the lower portion 2a of the hole 2 and part of the inner walls of the upper portion 2b thereof. It is also possible as another modification that the resistance-variable material layer 11 covers part of the inner walls of the lower portion 2a of the hole 2 and part of the inner walls of the upper portion 2b thereof as long as the resistance-variable material layer 11 contacts with each lead 13. It is also possible as another modification that the resistance-variable material layer 11 extends along the wall of the hole 2, so that the resistance-variable material layer 11 contacts with each lead 13.

As described above, the leads 13 and the first interconnection layer 23a are made of the same material so as to allow that the leads 13 and the first interconnection layer 23a are formed n the common processes. Further, the conductive portion 31 and the via contact 34 are made of the same material so as to allow that the conductive portion 31 and the via contact 34 are formed in the common processes. Furthermore, the conductive interconnection layer 32 and the second interconnection layer 35 are made of the same material so as to allow that the conductive interconnection layer 32 and the second interconnection layer 35 are formed in the common processes. The fuse structure 10b and the hole pattern 20a for peripheral circuit are thus formed in the fuse region 10 and the peripheral circuit region 20, respectively through partially common processes. These processes reduce the number of steps for manufacturing the semiconductor device. These processes allow efficient manufacturing of the semiconductor device.

### Third Embodiment

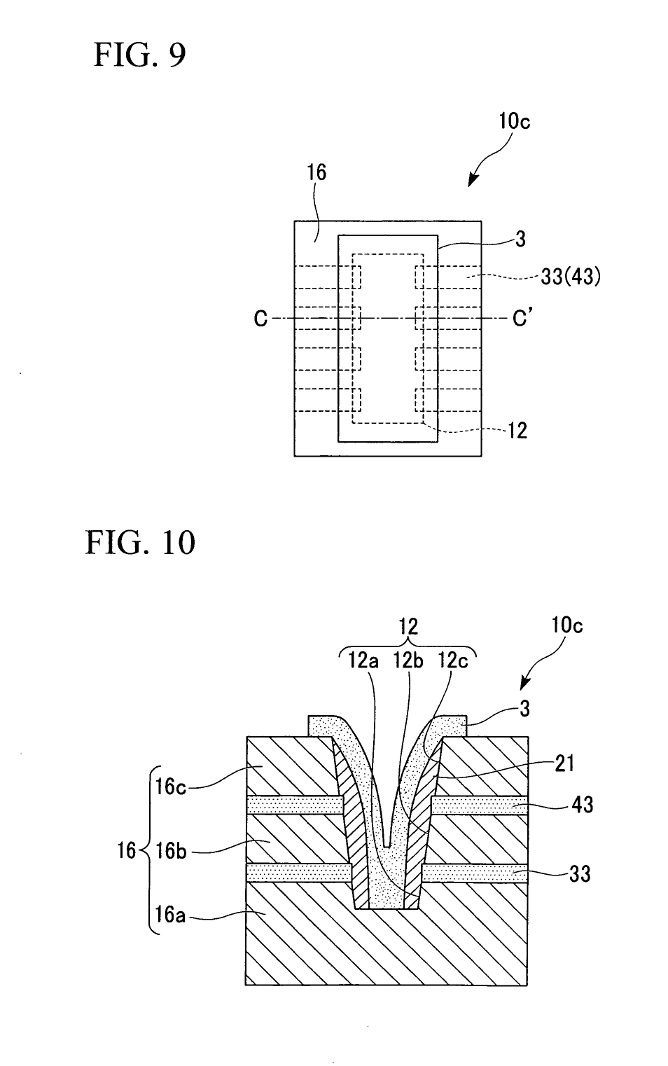

A third embodiment of the present invention will be described. FIG. 9 is a plain view illustrating a fuse structure that is provided in a semiconductor device in accordance with a third preferred embodiment of the present invention. FIG. 10 is a fragmentary cross sectional elevation view, taken along a C-C′ line of FIG. 9, which illustrates the fuse structure that is provided in the semiconductor device.

A fuse structure 10c may include an insulating layer 16. The insulating layer 16 may further include first, second and third insulating layers 16a, 16b and 16c. The second insulating layer 16b extends over the first insulating layer 16a. The third insulating layer 16c extends over the second insulating layer 16c. In some cases, the first, second and third insulating layers 16a, 16b and 16c may be made of silicon oxide.

The insulating layer 16 has a hole 12 which has one opening end and other closing end. The hole 12 may be modified to a slit or a groove. The hole 12 has a lower portion 12a, an intermediate portion 12b, and an upper portion 12c. The lower portion 12a of the hole 12 does not penetrate the first insulating layer 16a. The lower portion 12a of the hole 12 has one opening end and another closed end. The intermediate portion 12b of the hole 12 penetrates the second insulating layer 16b. The upper portion 12c penetrates the third insulating layer 16c. The hole 12 has inner walls. The lower portion 12a of the hole 12 has lower inner walls. The intermediate portion 12c of the hole 12 has intermediate inner walls. The upper portion 12c of the hole 12 has upper inner walls.

The fuse structure 10c may further include a resistance-variable material layer 21 that extends along the inner walls of the hole 12. In some cases, the resistance-variable material layer 21 may cover all of the inner walls of the lower and intermediate portions 12a and 12b of the hole 12 and also cover part of the inner walls of the upper portion 12b of the hole 12. The resistance-variable material layer 21 may not cover the bottom surface of the hole 12.

In typical case, the resistance-variable material layer 21 may be realized by a phase change material. A typical example of the phase change material for the resistance-variable material layer 21 may include, but is not limited to, chalcogenide. Examples of chalcogenide may include, but are not limited to, two or more of germanium (Ge), antimony (Sb), tellurium (Te), and selenium (Se). A typical example of the chalcogenide may include, but is not limited to, Ge₂Sb₂Te₅.

The fuse structure 10c may further include a reference power layer 3 which covers the bottom surface of the hole 12, the resistance-variable material layer 21 and a peripheral portion of the top surface of the insulator 16, wherein the peripheral portion surrounds the opening of the hole 12. A typical example of the reference power layer 3 may include, but is not limited to, tungsten. The reference power layer 3 contacts the resistance-variable material layer 21. The reference power layer 3 is adapted to be applied with a reference power voltage so as to allow the reference power layer 3 to perform as a common wiring of the fuse.

The fuse structure 10c may further include a plurality of first leads 33. In typical case, the plurality of first leads 33 extends over the first insulating layer 16a and under the second insulating layer 16b. Each first lead 33 has a first portion and a second portion, wherein the first portion reaches the wall of the hole 12 and which contacts with the resistance-variable material layer 21, and the second portion provides an electrical contact with an external device. In typical cases, the first portion may be a first end of the first lead 33 as shown in FIG. 10. The first portion or the first end of each first lead 33 can perform as a heater that heats the resistance-variable material layer 21, thereby changing the resistance of the resistance-variable material layer 21. The resistance-variable material layer 21 performs as the same number of fuses as the first leads 33 which contact with the resistance-variable material layer 21.

The fuse structure 10c may further include a plurality of second leads 43. In typical case, the plurality of first leads 33 extends over the second insulating layer 16b and under the third insulating layer 16c. Each second lead 43 has a first portion and a second portion, wherein the first portion reaches the wall of the hole 12 and which contacts with the resistance-variable material layer 21, and the second portion provides an electrical contact with an external device. In typical cases, the first portion may be a first end of the second lead 43 as shown in FIG. 10. The first portion or the first end of each second lead 43 can perform as a heater that heats the resistance-variable material layer 21, thereby changing the resistance of the resistance-variable material layer 21. The resistance-variable material layer 21 performs as the same number of fuses as the second leads 43 which contact with the resistance-variable material layer 21.

The resistance-variable material layer 21 performs as the same number of fuses as the total number of the first and second leads 33 and 43 which contact with the resistance-variable material layer 21.

A method of forming the fuse structure of the semiconductor device of FIGS. 9 and 10 will be described. A first silicon oxide film is formed over a metal oxide semiconductor structure or an interconnection layer. The first silicon oxide film can be formed by a chemical vapor deposition process. The first silicon oxide film may be then planarized by a chemical mechanical polishing process, thereby forming a first insulating layer 16a. The first insulating layer 16a is planarized to form a planarized surface thereof.

A tungsten film is formed over the planarized surface of the first insulating layer 16a. The tungsten film is patterned by a photo-lithography process and a dry etching process, thereby forming a plurality of first leads 33 over the planarized surface of the first insulating layer 16a.

A second silicon oxide film is formed over the plurality of first leads 33 and the planarized surface of the first insulating layer 16a. The second silicon oxide film can be formed by a chemical vapor deposition process. The second silicon oxide film may be then planarized by a chemical mechanical polishing process, thereby forming a second insulating layer 16b which extends over the plurality of first leads 33 and the planarized surface of the first insulating layer 16a. The second insulating layer 16b is planarized to form a planarized surface thereof.

A tungsten film is formed over the planarized surface of the second insulating layer 16b. The tungsten film is patterned by a photo-lithography process and a dry etching process, thereby forming a plurality of second leads 43 over the planarized surface of the second insulating layer 16b.

A third silicon oxide film is formed over the plurality of second leads 43 and the planarized surface of the second insulating layer 16b. The second silicon oxide film can be formed by a chemical vapor deposition process. The third silicon oxide film may be then planarized by a chemical mechanical polishing process, thereby forming a third insulating layer 16c which extends over the plurality of second leads 43 and the planarized surface of the second insulating layer 16b. The third insulating layer 16c is planarized to form a planarized surface thereof. The first, second and third insulating layers 16a, 16b and 16c in combination form an insulating layer 16.

The insulating layer 16 is selectively etched by a photo-lithography process and a dry etching process, thereby forming a hole 12 which has a lower portion 12a, an intermediate portion 12b and an upper portion 12c. The lower portion 12a of the hole 12 does not penetrate the first insulating layer 16a. The lower portion 12a of the hole 12 has one opening end and another closed end. The intermediate portion 12b of the hole 12 penetrates the second insulating layer 16b. The upper portion 12c of the hole 12 penetrates the third insulating layer 16c. The hole 12 has inner walls. The lower portion 12a of the hole 12 has lower inner walls. The intermediate portion 12b of the hole 2 has intermediate inner walls. The upper portion 12c of the hole 2 has upper inner walls. The first and second leads 33 and 43 reach the wall of the hole 2. The first portions or the first ends of each and second leads 33 and 43 are shown on the wall of the hole 12.

A phase change material film is formed on the bottom surface and the walls of the hole 12 and on the planarized surface of the third insulating layer 16c. The phase change material film contacts with the first portion or the first end of each of the first and second leads 33 and 43. The phase change material film is then etched back, thereby removing the phase change material film over the bottom surface of the hole 12 and over the planarized surface of the third insulating layer 16c, while leaving the phase change material film on all of the inner walls of the lower portion of the hole 12 and also on part of the inner walls of the upper portion of the hole 12. As a result, a resistance-variable material layer 21 is formed, which covers all of the inner walls of the lower and intermediate portions 12a and 12b of the hole 2 and also cover part of the inner walls of the upper portion 12c of the hole 12. The resistance-variable material layer 21 may not cover the bottom surface of the hole 12. The resistance-variable material layer 21 contacts the first portions or the first end of each if the first and second leads 33 and 34.

A tungsten film is formed, which covers the bottom surface of the hole 12, the resistance-variable material layer 21 and the planarized surface of the third insulating layer 16c. The tungsten film is patterned by a photo-lithography process and a dry etching process, thereby forming a reference power layer 3 which covers the bottom surface of the hole 12, the resistance-variable material layer 21 and a peripheral portion of the planarized surface of the insulator 16, wherein the peripheral portion surrounds the opening of the hole 12. The reference power layer 3 contacts with the resistance-variable material layer 21. As a result, the fuse structure 10c is completed.

Operations of the fuse structure 10c will be described with reference again to FIGS. 9 and 10. A current is applied across the resistance-variable material layer 21 between the reference power layer 3 and the plurality of first leads 33 and between the reference power layer 3 and the plurality of second leads 43, so as to change the resistance of the resistance-variable material layer 21. A pulse of current can be adjusted so as to control heat generation of the first portion or the first end of each of the first and second leads 33 and 43 which each performs as a heater. The current application heats contact portions of the resistance-variable material layer 21, wherein the contact portions contact with the first portions or the first ends of the first and second leads 33 and 43. Separate adjustment of the application of the current to each of the first and second leads 33 and 43 can separately control the temperature of each contact portion of the resistance-variable material layer 21 in contact with the first portion or the first end of each of the first and second leads 33 and 43. Separate control of the temperature of each contact portion of the resistance-variable material layer 21 can separately control the crystal state of each contact portion of the resistance-variable material layer 21 in contact with the first portion or the first end of each of the first and second leads 33 and 43. Separate control of the crystal state of each contact portion of the resistance-variable material layer 21 can separately control the contact resistance between each contact portion of the resistance-variable material layer 21 and each of the first and second leads 33 and 43.

In some cases, the pulse current applied through each of the first and second leads 33 and 43 to the resistance-variable material layer 21 can be adjusted in pulse width and pulse height to control the crystal state of the contact portion of the resistance-variable material layer 21, thereby controlling the resistance of the contact portion of the resistance-variable material layer 21.

When a pulse of current with a lower pulse height and a wider pulse width is applied through each of the first and second leads 33 and 43 to the resistance-variable material layer 21, crystallization is caused at the phase change material of the contact portion of the resistance-variable material layer 21 in contact with each of the first and second leads 33 and 43, thereby decreasing the resistance of the contact portion of the resistance-variable material layer 21.

When a pulse of current with a higher pulse height and a narrower pulse width is applied through each of the first and second leads 33 and 43 to the resistance-variable material layer 21, amorphization is caused at the phase change material of the contact portion of the resistance-variable material layer 21 in contact with each of the first and second leads 33 and 43, thereby increasing the resistance of the contact portion of the resistance-variable material layer 21.

Namely, adjustments in pulse width and height of the pulse current can control the transition of the phase or the crystal state of the contact portion of the resistance-variable material layer 21, thereby changing the resistance of the contact portion of the resistance-variable material layer 21.

The fuse structure 10c is configured to change the resistance between the reference power layer 3 and each of the first and second leads 33 and 43. Application of external electric signal through each of the first and second leads 33 and 43 to the resistance-variable material layer 21 can rewrite relief information and circuit interconnection information in a semiconductor device. The fuse structure 10c can rewrite relief information and circuit interconnection information in a semiconductor chip as packaged, by way of input of an external electric signal into the packaged semiconductor chip.

The semiconductor device includes the fuse structure 10c that includes the insulating layer 16 having the hole 12 having the walls, the resistance-variable material layer 21 extending along the walls of the hole 12, the reference power layer 3 covering the resistance-variable material layer 21, and each of the first and second leads 33 and 43. Each of the first and second leads 33 and 43 has the first portion that reaches the wall of the hole 12 and contacts with the resistance-variable material layer 21, and the second portion that is electrically connected to an external device. The resistance-variable material layer 21 performs as fuses. Namely, the resistance-variable material layer 21 has the contact portions that contact with the first portions of the first and second leads 33 and 43. Each contact portion of the resistance-variable material layer 21 performs a fuse. The resistance-variable material layer 21 has upper alignments of fuses and lower alignments of fuses.

The resistance-variable material layer 21 extends along the walls of the hole 12 of the insulating layer 16. The hole 12 has a depth direction that is parallel to the thickness direction of the insulating layer 16. The walls of the hole 12 extends in the thickness direction of the insulating layer 16. Thus, the resistance-variable material layer 21 extends in the thickness direction of the insulating layer 16. This layout of the resistance-variable material layer 21 extending in the thickness direction of the insulating layer 16 can further reduce the plain area necessary for layout for the fuses as compared to the layout for the resistance-variable material layer extending in parallel to the surface of the insulating layer 16. The layout of the resistance-variable material layer 21 extending in the thickness direction of the insulating layer 16 can increase the density of integration of the fuses as compared to the layout for the resistance-variable material layer extending in parallel to the surface of the insulating layer 16. The layout of the resistance-variable material layer 11 extending in the thickness direction of the insulating layer 16 does not need any via contact, thereby increasing the flexibility of design and layout of the fuses as compared to the fuse structure that needs the via contact.

The resistance-variable material layer 21 has multi-level alignments of fuse, for example, the upper alignments of fuses and lower alignments of fuses. The multi-level alignments of fuse, for example, the upper alignments of fuses and lower alignments of fuses can further reduce the plain area necessary for layout for the fuses as compared to the layout for the resistance-variable material layer extending in parallel to the surface of the insulating layer 16. The multi-level alignments of fuse, for example, the upper alignments of fuses and lower alignments of fuses can further increase the density of integration of the fuses as compared to the layout for the resistance-variable material layer extending in parallel to the surface of the insulating layer 16.

The layout for the resistance-variable material layer extending in parallel to the surface of the insulating layer 16 is the traditionally and historically employed layout that lies in the common technical sense to a person skilled in the art to which the invention pertains. The layout of the resistance-variable material layer 21 extending in the thickness direction of the insulating layer 16 is away from the technical common sense, for example, the traditionally and historically employed layout for the resistance-variable material layer but extending in parallel to the surface of the insulating layer 16. The upper alignments of the fuses and the lower alignments of the fuses is away from the technical common sense, for example, the traditionally and historically employed layout for the resistance-variable material layer but extending in parallel to the surface of the insulating layer 16.

The fuse structure that needs via contact is the traditionally and historically employed fuse structure which lies in the common technical sense to a person skilled in the art to which the invention pertains. The fuse structure free of any via contact is away from the technical common sense, for example, the traditionally and historically employed fuse structure that needs via contact. The fuse structure free of any via contact provides increased flexibility in laying out the fuses.

The materials variable for the resistance-variable material layer 21 may include, but are not limited to, the phase change materials, and other materials that vary in its resistivity upon heat application thereto by current application. Examples of the materials variable for the resistance-variable material layer 21 may include, but are not limited to, materials that vary in its resistivity upon application of a voltage or a current thereto, and the materials such as perovskite-type metal oxide that maintain the changed resistivity even after the voltage or current application was discontinued.

The materials available for the first and second leads 33 and 43 may be conductive materials such as metals, typical examples of which may include, but are not limited to, the above-described metal, aluminum and copper.

In the above-described embodiment, the resistance-variable material layer 21 covers all of the inner walls of the lower and intermediate portions 12a and 12b of the hole 12 and part of the inner walls of the upper portion 12c thereof. It is possible as a modification that the resistance-variable material layer 21 further covers the bottom of the hole 12 in addition to covering all of the inner walls of the lower and intermediate portions 12a and 12b of the hole 12 and part of the inner walls of the upper portion 12b thereof. It is also possible as another modification that the resistance-variable material layer 21 covers respective parts of the inner walls of the lower, intermediate and upper portions 12a, 12b and 12c of the hole 12 as long as the resistance-variable material layer 21 contacts with each of the first and second leads 33 and 34. It is also possible as another modification that the resistance-variable material layer 21 extends along the wall of the hole 12, so that the resistance-variable material layer 21 contacts with each of the first and second leads 33 and 34.

The above-described fuse structures 10a, 10b and 10c can be applicable to any semiconductor devices that need to rewrite relief information and circuit interconnection information after packaged, by way of input of an external electric signal into the packaged semiconductor device.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A fuse structure comprising:
an insulating layer having a hole;
a resistance-variable material layer disposed on inner wall of the hole;
a reference power layer that covers the resistance-variable material layer; and
a plurality of leads in the insulating layer, each lead having a first portion which reaches the inner wall of the hole and contacts the resistance-variable material layer, each lead being configured to allow an electrical connection to outside.

2. The fuse structure according to claim 1, wherein the resistance-variable material layer is made of a phase change material.

3. The fuse structure according to claim 1, wherein the resistance-variable material layer is made of perovskite-type metal oxide.

4. The fuse structure according to claim 1, wherein the insulating layer comprises a first insulating layer and a second insulating layer over the first insulating layer,
the hole comprises a lower portion in the first insulating layer and an upper portion in the second insulating layer,
the resistance-variable material layer covers at least part of inner wall of the lower portion of the hole and at least part of inner wall of the upper portion of the hole, and
the plurality of leads extends over the first insulating layer and under the second insulating layer.

5. The fuse structure according to claim 1, wherein the insulating layer comprises a first insulating layer, a second insulating layer over the first insulating layer, and a third insulating layer over the second insulating layer,
the hole comprises a lower portion in the first insulating layer, an intermediate portion in the second insulating layer, and an upper portion in the third insulating layer,
the resistance-variable material layer covers at least part of inner wall of the lower portion of the hole, at least part of inner wall of the intermediate portion of the hole, and at least part of inner wall of the upper portion of the hole, and
the plurality of leads comprises a first group of leads that extends over the first insulating layer and under the second insulating layer, and a second group of leads that extends over the second insulating layer and under the third insulating layer.

6. A semiconductor device including a fuse structure, the fuse structure comprising:
an insulating layer having a hole;
a resistance-variable material layer disposed on inner wall of the hole;
a reference power layer that covers the resistance-variable material layer; and
a plurality of leads in the insulating layer, each lead having a first portion which reaches the inner wall of the hole and contacts the resistance-variable material layer, each lead being configured to allow an electrical connection to outside.

7. The semiconductor device according to claim 6, wherein the resistance-variable material layer is made of a phase change material.

8. The semiconductor device according to claim 6, wherein the resistance-variable material layer is made of perovskite-type metal oxide.

9. The semiconductor device according to claim 6, wherein the insulating layer comprises a first insulating layer and a second insulating layer over the first insulating layer,
the hole comprises a lower portion in the first insulating layer and an upper portion in the second insulating layer,
the resistance-variable material layer covers at least part of inner wall of the lower portion of the hole and at least part of inner wall of the upper portion of the hole, and
the plurality of leads extends over the first insulating layer and under the second insulating layer.

10. The semiconductor device according to claim 6, wherein the insulating layer comprises a first insulating layer, a second insulating layer over the first insulating layer, and a third insulating layer over the second insulating layer,
the hole comprises a lower portion in the first insulating layer, an intermediate portion in the second insulating layer, and an upper portion in the third insulating layer,
the resistance-variable material layer covers at least part of inner wall of the lower portion of the hole, at least part of inner wall of the intermediate portion of the hole, and at least part of inner wall of the upper portion of the hole, and
the plurality of leads comprises a first group of leads that extends over the first insulating layer and under the second insulating layer, and a second group of leads that extends over the second insulating layer and under the third insulating layer.

11. A semiconductor device comprising:
an insulating layer comprising a first insulating layer and a second insulating layer over the first insulating layer, the insulating layer having a fuse region having a first hole and a peripheral circuit region having a second hole, the first hole comprising an lower portion in the first insulating layer and an upper portion in the second insulating layer,
a fuse structure in the first hole in the fuse region, the fuse structure comprising:
a resistance-variable material layer disposed on inner wall of the first hole;
a reference power layer comprising a conductive portion in the first hole and a conductive interconnection layer extending over the second insulating layer and the conductive portion, the conductive portion covering the resistance-variable material layer; and
a plurality of leads extending over the first insulating layer and under the second insulating layer in the fuse region, each lead having a first portion which reaches the inner wall of the hole and contacts the resistance-variable material layer, each lead being configured to allow an electrical connection to outside; and
a hole pattern for peripheral circuit in the second hole in the peripheral circuit region, the hole pattern comprising:
a first interconnection layer extending over the first insulating layer and under the second insulating layer in the peripheral circuit region;
a second interconnection layer extending over the second insulating layer in the peripheral circuit region; and
a via contact penetrating through the second insulating layer in the peripheral circuit region, the via contact providing an electrical connection between the first and second interconnection layers,
wherein the first interconnection layer and the plurality of leads are made of the same material,
the via contact and the conductive portion of the reference power layer are made of the same material, and
the second interconnection layer and the conductive interconnection layer of the reference power layer are made of the same material.

12. A method of forming a semiconductor device, the method comprising:
(a) forming a first insulating layer over a semiconductor substrate;
(b) forming first and second interconnection layers over the first insulating layer;
(c) forming a second insulating layer that covers the first and second interconnection layers;
(d) forming a first hole that penetrates the second insulating layer so that the edge portion of the first interconnection layer is shown on the inner wall of the first hole;
(e) forming a resistance-variable material layer on the inner wall of the first hole so that the resistance-variable material layer contacts the edge portion of the first interconnection layer;
(f) forming a second hole which penetrates the second insulating layer, so that a part of the second interconnection is shown through the second hole; and
(g) filling the first and second holes with a conductive material concurrently.

13. The method according to claim 12, wherein the first interconnection layer comprises a plurality of interconnection layers,
forming the first hole comprises forming the first hole so that the edge portions of the plurality of interconnection layers are shown on the inner wall of the first hole;

14. The method according to claim 12, wherein forming the first hole comprises forming a first hole that penetrates the second insulating layer and reaches an intermediate level of the first insulating layer.

15. The method according to claim 12, wherein the resistance-variable material layer is made of a phase change material.

16. The method according to claim 12, wherein the resistance-variable material layer is made of perovskite-type metal oxide.
